(19) United States
(12) Patent Application Publication
(10) Pub. No.: US 2010/0089744 A1
(43) Pub. Date: Apr. 15, 2010

(54) Method for Improving Adhesion of Films to Process Kits

(76) Inventors: Chia-Liang Chueh, Chiayi City (TW); Chang-Hui Chao, Hsin-Chu (TW); Jiun-Rong Pai, Jhubei City (TW); Yeh-Chieh Wang, Hsin-Chu (TW); Chihchous Chuang, Fongshan City (TW); Jia Chun Chen, Fongshan City (TW)

Correspondence Address: SLATER & MATSIL, L.L.P., 17950 PRESTON ROAD, SUITE 1000, DALLAS, TX, 75252, US

(21) Appl. No.: 12/569,462

(22) Filed: Sep. 29, 2009

Related U.S. Application Data
(60) Provisional application No. 61/104,617, filed on Oct. 10, 2008.
(60) Provisional application No. 61/186,260, filed on Jun. 11, 2009.

(51) Int. Cl. C23C 14/34; B23P 11/00

(52) U.S. Cl. 204/192.15; 29/428

(57) ABSTRACT

A method includes providing a process chamber including a target, wherein the target has a first coefficient of thermal expansion (CTE); selecting a process kit including a surface layer having a second CTE close to the first CTE; and installing the process kit in the process chamber with the surface layer exposed to the process chamber. A ratio of a difference between the first CTE and the second CTE is less than about 35 percent.

This application claims the benefit of U.S. Provisional Application No. 61/104,617 filed on Oct. 10, 2008, entitled “Method to Improve Film and Process Kit Adhesion with Film of Similar Material in Semiconductor Processing;” and U.S. Provisional Application No. 61/186,260 filed on Jun. 11, 2009, entitled “Method to Improve Film and Process Kit Adhesion with Film of Similar Material in Semiconductor Processing,” which applications are hereby incorporated herein by reference.

### TECHNICAL FIELD

This invention relates generally to apparatus for manufacturing integrated circuits, and particularly to the methods for reducing the peeling of deposited films on process kits.

### BACKGROUND

In the integrated circuit manufacturing processes, there are many steps involving the deposition of thin films on wafers. A commonly used deposition method of the thin films is physical vapor deposition (PVD), during which plasma is used to sputter ions from targets, and to deposit the sputtered ions on wafers. However, during the PVD processes, the wafers are susceptible to the contamination coming from inside the process chambers.

During the deposition processes, the materials deposited on the wafers are also deposited on the internal components of the process chambers. With the increase in the thickness of the accumulated materials, the accumulated materials eventually peel off and fall on the wafers, resulting in yield loss.

In order to reduce the contamination coming from the process chamber, process kits are often used to shield the internal components of the process chamber and to collect the ions sputtered from targets. The process kits, however, need to be maintained and replaced periodically. Otherwise, the materials deposited on the process kits also crack due to stress, and peel off. Conventionally, scrubbings, for example, using high-pressure water and/or brushes, are performed to remove the peeled-off particles from the wafers after the PVD processes, and the scrubbings may reduce the yield loss by 50 percent or more. However, the source of the contamination still has not been reduced. In particular, the cost of process maintenance required for maintaining the process chambers and the cost of new process kits are significant. Therefore, there is a need to reduce the required maintenance and to prolong the lifetime of process kits.

### SUMMARY OF THE INVENTION

In accordance with one aspect of the present invention, a method includes providing a process chamber including a target, wherein the target has a first coefficient of thermal expansion (CTE); selecting a process kit including a surface layer having a second CTE close to the first CTE; and installing the process kit in a process chamber with the surface layer exposed to the process chamber. A ratio of a difference between the first CTE and the second CTE is less than about 35 percent.

In accordance with another aspect of the present invention, a method includes providing a process kit including a base layer; forming a surface layer over the base layer of the process kit using plasma spray, wherein the surface layer includes titanium and has a first CTE; installing the process kit in a process chamber; and, after the step of installing the process kit, depositing a film on a wafer in the process chamber. The film includes titanium nitride and has a second CTE close to the first CTE.

In accordance with yet another aspect of the present invention, a method includes providing a base layer of a process kit; and forming a surface layer over and adjoining the base layer of the process kit using plasma spray. The surface layer includes a material selected from the group consisting essentially of titanium, tantalum, and aluminum. The process kit is installed in a process chamber, which has a target comprising a same metal as the surface layer. The target has a coefficient of thermal expansion (CTE) close to a CTE of the surface layer.

The advantageous features of the present invention include improved adhesion of process films on process kits, improved lifetime of process kits, and reduced periods of time between the maintenances of process kits.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a process chamber for depositing a film on a wafer, wherein process kits are installed in the process chamber;

FIG. 2 illustrates a cross-sectional view of a portion of a conventional process kit; and

FIG. 3 illustrates a process kit including a stress reduction layer in the process kit.

### DETAILED DESCRIPTION OF ILLUSTRATIVE EMBODIMENTS

The making and using of the embodiments of the present invention are discussed in detail below. It should be appreciated, however, that the embodiments provide many applicable inventive concepts that can be embodied in a wide variety of specific contexts. The specific embodiments discussed are merely illustrative of specific ways to make and use the invention, and do not limit the scope of the invention.

A novel method for reducing the contamination in process chambers and the respective process kits are presented. The variations of the embodiment are discussed. Throughout the various views and illustrative embodiments of the present invention, like reference numbers are used to designate like elements.

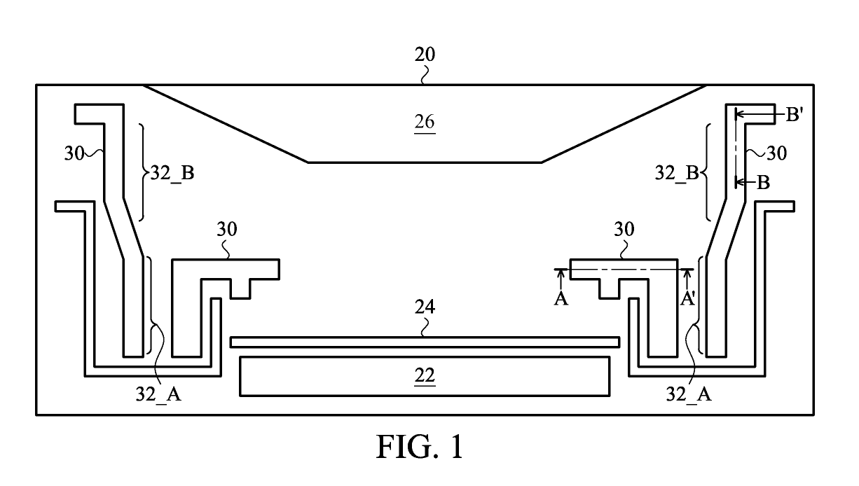

FIG. 1 illustrates process chamber 20, which may be used for physical vapor deposition (PVD), although process chamber 20 may also be used for other deposition methods. Process chamber 20 includes pedestal 22, which may include a heater that may be an electrostatic chuck (E-Chuck). Wafer 24 is placed on pedestal 22. On top of pedestal 22 (and wafer 24) is target 26, which comprises the materials that are to be deposited on wafer 24 to form a film. Process chamber 20 further includes process kit(s) 30. Process kit 30 may be an integrated component, or include a plurality of components including, but not limited to, an upper shield, a bottom shield, a cover ring, and the like. In a top view, process kit 30 may appear as one or a plurality of rings that encircle wafer 24. During the deposition of films onto wafer 24, process kit 30 acts as a shield(s) to prevent the materials sputtered from target 26 from being deposited onto undesirable locations, such as the sidewalls of process chamber 20.

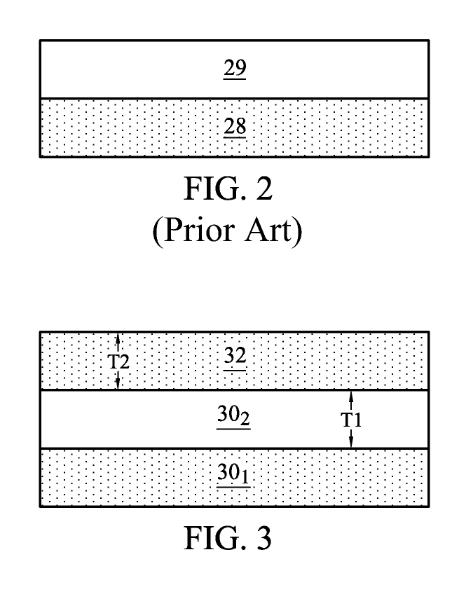

FIG. 2 illustrates a cross-sectional view of a portion of conventional process kit 28, which may be formed of stainless steel. During the use of process kit 28, additional materials coming from targets may be deposited on process kit 28. For example, during the deposition of titanium and/or titanium nitride (referred to as Ti/TiN hereinafter) onto wafers, Ti/TiN film 29 is deposited onto process kit 28. Experiments have revealed that when process kit 28 as shown in FIG. 2 is used, high production yield loss resulted. For example, it has been found that about 68 percent of yield loss resulted from the peeled-off Ti/TiN, which falls on wafers. Also, about 17 percent of yield loss resulted from the peeled-off aluminum since the same process chamber that is used to deposit Ti/TiN films is also used to deposit aluminum or aluminum copper.

In the structure as shown in FIG. 2, stainless steel process kit 28 has a coefficient of thermal expansion (CTE) of about 19×10⁻⁶/C (Celsius), while Ti/TiN film 29 has a CTE of about 9.35×10⁻⁶/C. Such a significant difference in CTE results in significant stress in Ti/TiN film 29. As a result, Ti/TiN film 29 is prone to cracking and peeling. The particles peeled-off from Ti/TiN process film 29 hence will result in the yield loss of the wafers.

FIG. 3 illustrates a cross-sectional view of an embodiment of the present invention, wherein the cross-sectional view may be made either along the plane crossing line A-A′, or along the plane crossing line B-B′ in FIG. 1. Process kit 30 includes base layer 30₁ and stress reduction layer 30₂. Throughout the description, stress reduction layer 30₂ is also referred to a surface layer since at the time process kit 30 is installed in process chamber 20, stress reduction layer 30₂ is exposed. In an embodiment, base layer 30₁ comprises stainless steel, although other materials, such as aluminum, titanium, tantalum, copper, alloys thereof, and/or combinations thereof, may also be used. Stress reduction layer 30₂ may be formed of titanium, tantalum, aluminum, copper, titanium, tantalum, cobalt, tungsten, and/or other materials, including Mg, Ca, Sr, Ba, SC, Y, La, Ce, Ti, Zr, Hf, Pr, V, Nb, Ta, Nd, Cr, Mo, W, Mn, Re, Sm, Fe, Ru, Os, Eu, Co, Rh, Ir, Gd, Ni, Pd, Pt, Tb, Cu, Ag, Au, Dy, Zn, Ho, Ga, In, Er, Ge, In, Ge, Pb, Tm, YB, Lu, Bi, C, and the like. Stress reduction layer 30₂ is pre-formed before process kit 30 is installed in process chamber 20 (refer to FIG. 1) and used in the shielding for the depositions on wafers. After being used in process chamber 20, an additional film (referred to as process film 32 hereinafter, as it is formed by an integrated circuit manufacturing process) is formed. To reduce the stress in process film 32 and reduce the peeling of process film 32 from stress reduction layer 30₂, process film 32 may have characteristics close to that of the underlying stress reduction layer 30₂. For example, the CTE of process film 32 may be close to that of stress reduction layer 30₂. Assuming the CTE of process film 32 is C1, and the CTE of stress reduction layer 30₂ is C2, the CTE difference, which may be expressed as |C1-C2|/C1, may be less than about 35 percent, and even less than about 7 percent. CTE C1 and CTE C2 may also be equal to each other. Since the materials of process film 32 come from target 26, the materials of target 26 have essentially the same characteristics, including the CTE, as that of process film 32. In other words, process kit 30 and the respective stress reduction layer 30₂ need to be selected according to the films (and hence target 26) to be formed on wafer 24. The thickness of stress reduction layer 30₂ may be greater than about 37 μm, or between about 150 μm and about 300 μm.

In an exemplary embodiment, stress reduction layer 30₂ comprises titanium, and may be formed of substantially pure titanium, for example, with the atomic percentage of titanium in stress reduction layer 30₂ being greater than about 70 percent. Titanium stress reduction layer 30₂ has a CTE equal to about 8.7×10⁻⁶/C. Accordingly, the respective process kit 30 comprising titanium stress reduction layer 30₂ may be used to form titanium layers, titanium nitride layers, or the like. Since titanium nitride has a CTE close to about 9.35×10⁻⁶/C, the stress in the resulting process film 32, which also comprises titanium or titanium nitride, will be small, and the likelihood of cracking and peeling is reduced. It is realized that although process film 32 may have a similar material as that of stress reduction layer 30₂, for example, with both having titanium, stress reduction layer 30₂ may have a substantially uniform thickness T1 (FIG. 3), while process film 32 may have different thicknesses T2 from one location to the other. For example, in FIG. 1, process film portion 32_A may have a thickness less than about 50 percent of the thickness of process film portion 32_B since process film portion 32_A has less exposure to the sputtered ions than process film portion 32_B.

To reduce the peeling of stress reduction layer 30₂ from base layer 30₁, stress reduction layer 30₂ needs to have a good bonding with base layer 30₁. In an embodiment, the good bonding between stress reduction layer 30₂ and process film 32 may be achieved by depositing stress reduction layer 30₂ on base layer 30₁ using plasma spray, which involves high voltages, for example, higher than about 50 volts. Also, higher temperatures may be used in the plasma spray, with the temperatures at the interface region between stress reduction layer 30₂ and base layer 30₁ being higher than about 1,000° C., for example. Stress reduction layer 30₂ and base layer 30₁ thus have a good bonding not prone to peeling, even if stress reduction layer 30₂ may be under a relatively great stress level due to the high degree of CTE mismatch. On the other hand, stress reduction layer 30₂ and the overlying process film 32 are formed of similar materials, and hence have similar CTEs. Accordingly, process film 32 suffers less from stress and peeling.

To further improve the bonding between process film 32 and stress reduction layer 30₂, the surface roughness of stress reduction layer 30₂ may be controlled in a desirable range. In an embodiment, the surface roughness of stress reduction layer 30₂ may be greater than about 10 ra, and may be between about 15 ra and about 30 ra. The adjustment of the surface roughness of stress reduction layer 30₂ may be performed by adjusting the process conditions of the plasma spray, for example power, pressure, or the like.

If different films are to be formed on wafer 24 (please refer to FIG. 1), process kits with different stress reduction layers may be selected to match the CTE of process films 32 that will be deposited on the process kits with the CTE of the respective stress reduction layer 30₂. In an embodiment, wafer 24 is to be deposited with an aluminum film or an alloy film of aluminum and copper (AlCu). In the embodiment shown in FIG. 3, process film 32 may include aluminum or AlCu. Stress reduction layer 30₂ may thus be formed of aluminum alloy, pure aluminum, or substantially pure aluminum, for example, with the atomic percentage of aluminum being greater than about 70 percent. The aluminum stress reduction layer 30₂ has a good bonding with the underlying base layer 30₁, which may be formed of stainless steel or other materials, as discussed in the preceding paragraphs. Accordingly, the formation methods of aluminum stress reduction layer 30₂ may include plasma spray.

In alternative embodiments, wafer 24 is to be deposited with a tantalum film or a tantalum nitride (TaN) film. Accordingly, in the embodiment shown in FIG. 3, process film 32 may include tantalum or TaN. Stress reduction layer 30₂ may be formed of tantalum alloy, pure tantalum, or substantially pure tantalum, for example, with the atomic percentage of tantalum being greater than about 70 percent. The tantalum stress reduction layer 30₂ has a good bonding with the underlying base layer 30₁, which may be formed of stainless steel or other materials, as discussed in the preceding paragraphs. Accordingly, the formation methods of tantalum stress reduction layer 30₂ may include plasma spray.

Advantageously, by using the embodiments of the present invention, the peeling of process films 32 from process kit 30 may be significantly reduced due to the reduced stress in process films 32, and better adhesion of process films to the process kit may be achieved due to the similarity in materials. Experiment results have revealed that by using the above-discussed embodiments, the lifetime of the process kits is doubled over conventional process kits. Further, the process maintenance time per process kit is also reduced by about one-half since the interval between the process maintenances is also doubled.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps. In addition, each claim constitutes a separate embodiment, and the combination of various claims and embodiments are within the scope of the invention.

What is claimed is:

1. A method comprising:
providing a process chamber comprising a target, wherein the target has a first coefficient of thermal expansion (CTE);
selecting a process kit comprising a surface layer having a second CTE, wherein a ratio of a difference between the first CTE and the second CTE is less than about 35 percent; and
installing the process kit in a process chamber with the surface layer exposed to the process chamber.

2. The method of claim 1 further comprising, after the step of installing the process kit, depositing a film on a wafer by sputtering from the target.

3. The method of claim 1 further comprising forming the surface layer on the process kit using plasma spray.

4. The method of claim 1, wherein the surface layer of the process kit and the target comprise a same material.

5. The method of claim 1, wherein the process kit comprises a stainless steel layer underlying and adjoining the surface layer.

6. A method comprising:
providing a process kit comprising a base layer;
forming a surface layer over the base layer of the process kit using plasma spray, wherein the surface layer comprises titanium and has a first coefficient of thermal expansion (CTE);
installing the process kit in a process chamber; and
after the step of installing the process kit, depositing a film on a wafer in the process chamber, wherein the film comprises titanium nitride and has a second CTE close to the first CTE.

7. The method of claim 6, wherein at a time the process kit is installed in the process chamber, the surface layer is exposed.

8. The method of claim 6, wherein the first CTE and the second CTE have less than about 35 percent difference.

9. The method of claim 6, wherein the surface layer comprises tantalum, and wherein the film comprises tantalum nitride.

10. The method of claim 6, wherein the surface layer comprises aluminum, and wherein the film comprises aluminum copper.

11. The method of claim 6, wherein the base layer comprises a stainless steel layer adjoining the surface layer.

12. A method comprising:
providing a base layer of a process kit;
forming a surface layer over and adjoining the base layer of the process kit using plasma spray, wherein the surface layer comprises a material selected from the group consisting essentially of titanium, tantalum, and aluminum; and
installing the process kit in a process chamber, wherein the process chamber comprises a target comprising a same metal as the surface layer, and has a first coefficient of thermal expansion (CTE) close to a second CTE of the surface layer.

13. The method of claim 12 further comprising:
after the step of installing the process kit, depositing a film on a wafer in the process chamber by sputtering from the target.

14. The method of claim 13, wherein the surface layer comprises titanium, and wherein the film comprises titanium nitride.

15. The method of claim 13, wherein the surface layer comprises tantalum, and wherein the film comprises tantalum nitride.

16. The method of claim 13, wherein the surface layer comprises aluminum, and wherein the film comprises aluminum copper.
